(19) United States
(12) Patent Application Publication
(10) Pub. No.: US 2024/0268154 A1
(43) Pub. Date: Aug. 8, 2024

(54) DISPLAY DEVICE AND METHOD FOR MANUFACTURING THE SAME

(71) Applicant: Samsung Display Co., LTD., Yongin-si, Gyeonggi-do (KR)

(72) Inventor: CHUNGI YOU, Yongin-si (KR)

(21) Appl. No.: 18/407,707

(22) Filed: Jan. 9, 2024

(30) Foreign Application Priority Data
Feb. 3, 2023 (KR) 10-2023-0027990

(51) Int. Cl. H10K 59/122; H10K 59/12

(52) U.S. Cl. CPC H10K 59/122; H10K 59/1201

(57) ABSTRACT

A display device includes a substrate, a via-insulating layer on the substrate, a first pixel electrode on the via-insulating layer, a first pixel defining layer having a flat upper surface, on the via-insulating layer, and defining an opening exposing at least a portion of an upper surface of the first pixel electrode, and separators on the first pixel defining layer and spaced apart from each other in a plan view.

### CROSS-REFERENCE TO RELATED APPLICATION

This application claims priority to and the benefit of Korean Patent Application No. 10-2023-0027990, filed on Mar. 2, 2023, in the Korean Intellectual Property Office, the content of which is herein incorporated by reference in its entirely.

### BACKGROUND

### 1. Field

Aspects of the present disclosure relates to a display device and a method for manufacturing the same. More particularly, the present disclosure relates to a display device that provides visual information and a method for manufacturing the same.

### 2. Description of the Related Art

With the development of information technology, the importance of a display device, which is a connection medium between a user and information, has been highlighted. For example, the use of display devices such as liquid crystal display device (“LCD”), organic light emitting display device (“OLED”), plasma display device (“PDP”), quantum dot display device or the like is increasing.

Recently, a head mounted display (HMD) including such a display device has been developed. The head-mounted display is a glasses-type monitor device of virtual reality (VR) or augmented reality (AR) that is worn in the form of glasses or a helmet and focuses on a distance close to the user's eyes. The head-mounted display may provide an image displayed on the display device to the user's eyes through a lens.

The above information disclosed in this Background section is only for enhancement of understanding of the background of the invention and therefore it may contain information that does not form the prior art.

### SUMMARY

Aspects of embodiments of the present disclosure are directed to a display device with reduced power consumption.

Aspects of embodiments of the present disclosure are directed to a method of manufacturing the display device.

According to some embodiments, there is provided a display device including: a substrate; a via-insulating layer on the substrate; a first pixel electrode on the via-insulating layer; a first pixel defining layer having a flat upper surface, on the via-insulating layer, and defining an opening exposing at least a portion of an upper surface of the first pixel electrode; and separators on the first pixel defining layer and spaced apart from each other in a plan view.

In some embodiments, the first pixel defining layer includes: a first portion defining the opening; and a second portion having surfaces covered by the first portion.

In some embodiments, the first pixel defining layer includes an inorganic material, and the first portion includes an inorganic material different from that of the second portion.

In some embodiments, the first portion includes silicon nitride, and the second portion includes silicon oxide.

In some embodiments, each of the separators includes a first inorganic layer and a second inorganic layer on the first inorganic layer, and the first inorganic layer includes an inorganic material different from the second inorganic layer.

In some embodiments, a side surface of the second inorganic layer protrudes more in a direction away from a center of the first inorganic layer than a side surface of the first inorganic layer.

In some embodiments, the display device further includes: a second pixel defining layer between the first pixel defining layer and the separators, wherein the second pixel defining layer overlaps the first pixel defining layer in the plan view.

In some embodiments, a side surface of the first pixel defining layer protrudes more in a direction away from a center of the second pixel defining layer than a side surface of the second pixel defining layer.

In some embodiments, the substrate includes: a base substrate defining a plurality of grooves and including a silicon wafer; and a plurality of pixel circuit portions respectively accommodated in the plurality of grooves.

In some embodiments, the display device further includes: a second pixel electrode and a third pixel electrode on the via-insulating layer; and first, second, and third light emitting layers respectively on an upper surface of the first, second, and third pixel electrodes, wherein the first light emitting layer, the second light emitting layer, and the third light emitting layer emit lights have different wavelengths.

According to some embodiments, there is provided a method for manufacturing a display device, the method including: forming a via-insulating layer on a substrate; forming a first pixel electrode on the via-insulating layer; forming a first preliminary layer defining a groove on the via-insulating layer and the first pixel electrode; forming a second preliminary layer that fills the groove on the first preliminary layer; forming a second portion of a first pixel defining layer that fills the groove and has a flat upper surface by removing a portion of the second preliminary layer; forming separators spaced apart from each other in a plan view on the second portion of the first pixel defining layer; and forming a first portion of the first pixel defining layer that defines an opening exposing at least a portion of an upper surface of the first pixel electrode and has a flat upper surface by patterning the first preliminary layer.

In some embodiments, the first preliminary layer is formed along profiles of the via-insulating layer and the first pixel electrode.

In some embodiments, the first pixel defining layer includes an inorganic material, and the first portion includes an inorganic material different from the second portion.

In some embodiments, the forming of the second portion of the first pixel defining layer is performed through a polishing process.

In some embodiments, each of the separators includes a first inorganic layer and a second inorganic layer on the first inorganic layer, and the first inorganic layer includes an inorganic material different from that of the second inorganic layer.

In some embodiments, a side surface of the second inorganic layer protrudes more in a direction away from a center of the first inorganic layer than a side surface of the first inorganic layer.

In some embodiments, the method further includes: forming a second pixel defining layer on the first preliminary layer and the second portion of the first pixel defining layer after the forming the second portion of the first pixel defining layer, wherein the second pixel defining layer is between the second portion of the first pixel defining layer and the separators.

In some embodiments, a side surface of the first portion of the first pixel defining layer protrudes more in a direction away from a center of the second pixel defining layer than a side surface of the second pixel defining layer.

In some embodiments, the substrate includes a silicon wafer.

In some embodiments, the forming a first pixel electrode includes: forming a second pixel electrode and a third pixel electrode on the via-insulating layer, wherein the method further includes: forming first, second, and third light emitting layers respectively on an upper surface of the first, second, and third pixel electrodes, and wherein the first light emitting layer, the second light emitting layer, and the third light emitting layer are configured to emit lights having different wavelengths.

Other aspects, features, and characteristics that are not described above will be more clearly understood from the accompanying drawings, claims, and detailed description.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to some embodiments of the present disclosure.

FIG. 2 is a cross-sectional view taken along the line I-I′ of FIG. 1, according to some embodiments of the present disclosure.

FIG. 3 is an enlarged cross-sectional view of the area ‘A’ of FIG. 2, according to some embodiments of the present disclosure.

FIG. 4 is a cross-sectional view taken along the line II-II′ of FIG. 1, according to some embodiments of the present disclosure.

FIGS. 5, 6, 7, 8, 9, 10, and 11 are cross-sectional views illustrating a method for manufacturing a display device according to some embodiments of the present disclosure.

FIG. 12 is a cross-sectional view illustrating a display device according to some other embodiments of the present disclosure.

FIG. 13 is an enlarged cross-sectional view of the area ‘B’ of FIG. 12, according to some embodiments of the present disclosure.

FIGS. 14, 15, 16, and 17 are cross-sectional views illustrating a method for manufacturing a display device according to some other embodiments of the present disclosure.

### DETAILED DESCRIPTION

Hereinafter, some embodiments of the present disclosure will be described in detail with reference to the accompanying drawings. The same reference numerals are used for the same components in the drawings, and redundant descriptions of the same components will be omitted.

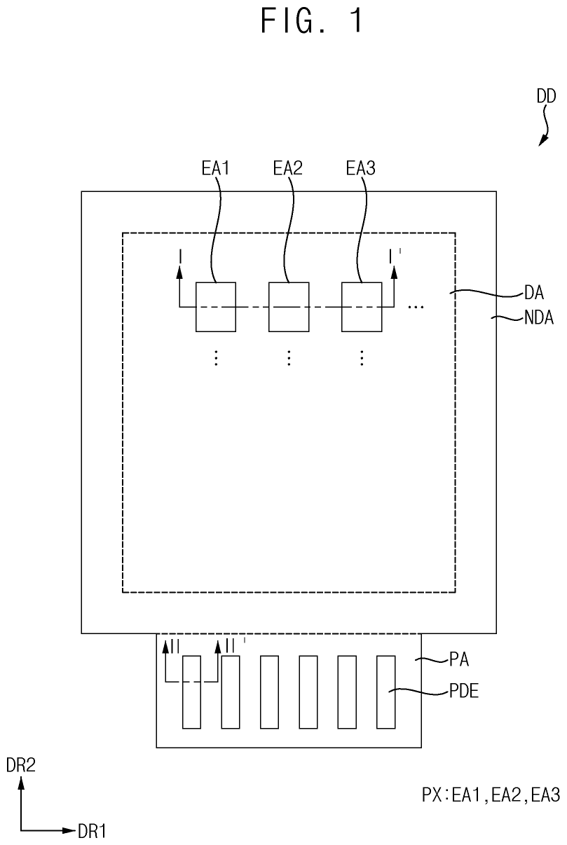

FIG. 1 is a plan view illustrating a display device according to some embodiments of the present disclosure.

As used herein, a plane may be defined by a first direction DR1 and a second direction DR2 crossing the first direction DR1. For example, the first direction DR1 and the second direction DR2 may be perpendicular to each other. A display device DD and various components or layers thereof may have a thickness extended along a third direction which crosses or intersects the plane, that is, each of the first direction DR1 and the second direction DR2.

Referring to FIG. 1, the display device DD according to some embodiments of the present disclosure includes a display area DA and a non-display area NDA.

The display area DA may be defined as an area for displaying an image. A planar shape of the display area DA may be a rectangular shape. However, the planar shape of the display area DA is not limited thereto, and the display area DA may have various planar shapes such as a circular shape, an elliptical shape, a polygonal shape, or the like.

A plurality of pixels PX for generating an image may be disposed in the display area DA. The image may be generated by combining light emitted from each of the pixels PX. That is, each of the pixels PX may be defined as a minimum light emitting unit capable of emitting light. For example, the pixels PX may be arranged in a matrix form along the first and second directions DR1 and DR2.

Each of the pixels PX may include a first light emitting area EA1, a second light emitting area EA2, and a third light emitting area EA3 that emit light. Although FIG. 1 illustrates that each of the pixels PX includes three light emitting areas EA1, EA2, and EA3, the present disclosure is not limited thereto. For example, each of the pixels PX may include four or more light emitting areas.

Each of the first light emitting area EA1, the second light emitting area EA2, and the third light emitting area EA3 may refer to an area in which light emitted from a light emitting element is emitted to the outside of the display device DD. For example, the first light emitting area EA1 may emit a first light, the second light emitting area EA2 may emit a second light, and the third light emitting area EA3 may emit a third light. In some embodiments, the first light is red light, the second light is green light, and the third light is blue light. However, the present disclosure is not limited thereto. For example, the pixels PX may be combined to emit yellow, cyan, and magenta lights. In addition, the pixels PX may be combined to further emit white light.

Signal lines, such as gate lines and data lines, may be disposed in the display area DA. The signal lines may be connected to each of the pixels PX. Each of the pixels PX may receive a gate signal, a data signal, and the like from the signal lines.

The non-display area NDA may be defined as an area that is configured not to display an image. The non-display area NDA may be positioned around the display area DA. For example, the non-display area NDA may surround the display area DA in a plan view. Drivers for displaying an image in the display area DA may be disposed in the non-display area NDA.

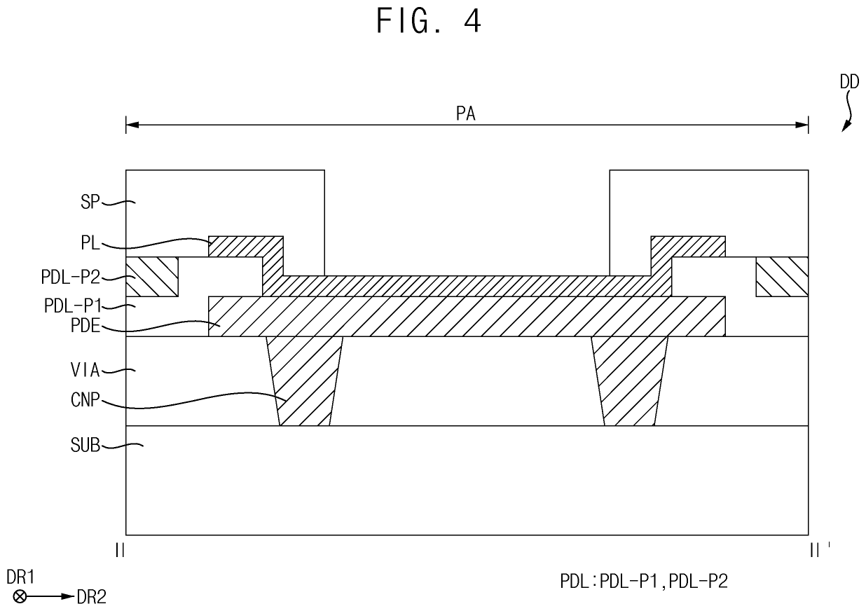

The non-display area NDA may include a pad area PA. The pad area PA may be positioned on one side of the display area DA. For example, the pad area PA may be spaced apart from (e.g., separated/offset from) the display area DA in the second direction DR2. The pad area PA may extend in the first direction DR1. A plurality of pads may be disposed in the pad area PA. In other words, a plurality of pad electrodes PDE may be disposed in the pad area PA. The pad electrodes PDE may be disposed to be spaced apart from each other in the first direction DR1. The pad electrodes PDE may be connected to a printed circuit board (PCB). For example, each of the pad electrodes PDE may include a metal, an alloy, a metal nitride, a conductive metal oxide, a transparent conductive material, or the like. These may be used alone or in combination with each other. A detailed description of the pad area PA will be provided later with reference to FIG. 4.

The display device DD according to some embodiments of the present invention is a display device displaying an image. For example, the display device DD may be a display device such as an organic light emitting display device, a liquid crystal display device, an organic light emitting diode on silicon substrate (OLEDos), a liquid crystal on silicon substrate (LCos), or a light emitting diode on silicon substrate

(LEDos). In some embodiments, the display device DD is a display device such as OLEDos.

For example, if the display device DD is a display device such as OLEDos, the display device DD may configure a head-mounted display, which is a virtual reality or augmented reality glasses-type monitor device that is worn in the form of glasses or a helmet and focuses on a distance close to the user's eyes. However, the present disclosure is not limited thereto, and the display device DD may be part of various other suitable displays.

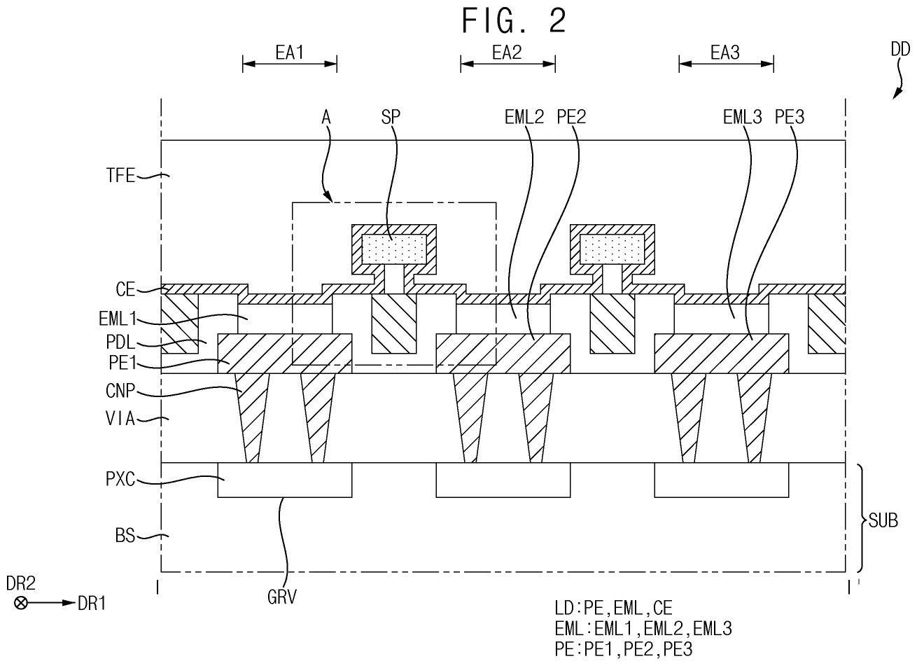

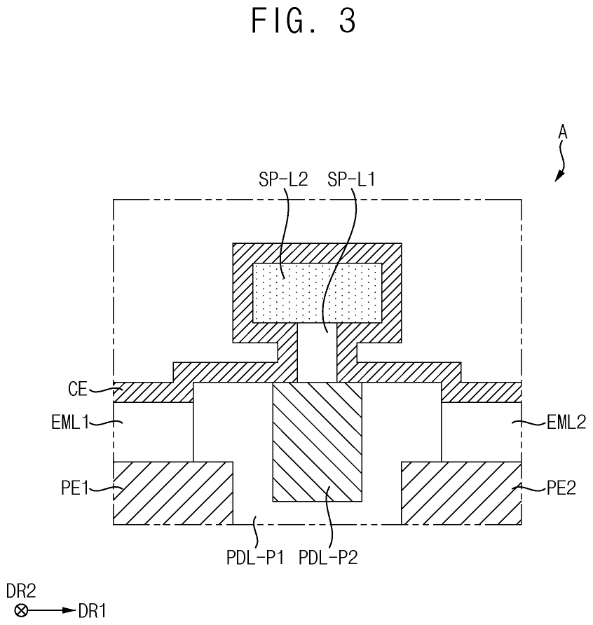

FIG. 2 is a cross-sectional view taken along the line I-I′ of FIG. 1, according to some embodiments of the present disclosure. FIG. 3 is an enlarged cross-sectional view of the area ‘A’ of FIG. 2, according to some embodiments of the present disclosure.

Referring to FIGS. 2 and 3, the display device DD may include a substrate SUB, a via-insulating layer VIA, a connection pattern CNP, a light emitting element LD, a pixel defining layer PDL, separators SP, and an encapsulation layer TFE. The light emitting element LD may include a pixel electrode PE, a light emitting layer EML, and a common electrode CE.

The substrate SUB may include a base substrate BS and a plurality of pixel circuit parts PXC. In some embodiments, the substrate SUB is a semiconductor circuit board. The substrate SUB may include a silicon wafer.

The base substrate BS may define a plurality of grooves GRV. The pixel circuit parts PXC may be accommodated in (e.g., positioned in) the plurality of grooves GRV, respectively.

Each of the pixel circuit parts PXC may include at least one transistor. In addition, each of the pixel circuit parts PXC may further include at least one capacitor.

A via-insulating layer VIA may be disposed on the substrate SUB. The via-insulating layer VIA may include an organic material and/or an inorganic material. Examples of the organic material that may be used as the via-insulating layer VIA may include photoresist, polyimide resin, polyamide resin, siloxane resin, acrylic resin, or the like. These may be used alone or in combination with each other.

In some embodiments, the via-insulating layer VIA defines a via opening. The via opening may expose a portion of the pixel circuit parts PXC (e.g., in a plan view).

The connection pattern CNP may be disposed on the substrate SUB. For example, the connection pattern CNP may be disposed in the via opening defined by the via-insulating layer VIA. The connection pattern CNP may electrically connect the pixel circuit parts PXC and the pixel electrode PE. The connection pattern CNP may include a metal, an alloy, a metal nitride, a conductive metal oxide, a transparent conductive material, and/or the like. Examples of materials that may be used as the connection pattern CNP may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. These may be used alone or in combination with each other. In some embodiments, the connection pattern CNP includes tungsten (W).

The pixel electrode PE may be disposed on the via-insulating layer VIA and the connection pattern CNP. The pixel electrode PE may be connected to the pixel circuit parts PXC through the connection pattern CNP. The pixel electrode PE may include a metal, an alloy, a metal nitride, a conductive metal oxide, a transparent conductive material, or the like. These may be used alone or in combination with each other. For example, the pixel electrode PE may serve as an anode electrode.

In some embodiments, the pixel electrode PE includes a first pixel electrode PE1, a second pixel electrode PE2, and a third pixel electrode PE3. The first pixel electrode PE1 may be disposed on the via-insulating layer VIA and the connection pattern CNP in the first light emitting area EA1. The second pixel electrode PE2 may be disposed on the via-insulating layer VIA and the connection pattern CNP in the second light emitting area EA2. The third pixel electrode PE3 may be disposed on the via-insulating layer VIA and the connection pattern CNP in the third light emitting area EA3.

In some embodiments, the pixel electrode PE is a (semi-)transmissive electrode or a reflective electrode. For example, the pixel electrode PE may include a reflective layer formed of silver (Ag), magnesium (Mg), aluminum (Al), platinum (Pt), palladium (Pd), gold (Au), nickel (Ni), neodymium (Nd), iridium (Ir), chromium (Cr), or a compound thereof, and a transparent or translucent electrode layer formed on the reflective layer. Examples of materials that may be used as the transparent or translucent electrode layer may include indium tin oxide (ITO), indium zinc oxide (IZO), zinc oxide (ZnO), aluminum zinc oxide (AZO), or the like. These may be used alone or in combination with each other.

The pixel electrode PE may have a multilayer structure. For example, the pixel electrode PE may include a first electrode layer including indium tin oxide (ITO), a second electrode layer disposed on the first electrode layer and including silver (Ag), and a third electrode layer disposed on the second electrode layer and including indium tin oxide (ITO).

The pixel defining layer PDL may be disposed on the via-insulating layer VIA and the pixel electrode PE. The pixel defining layer PDL may define a pixel opening that covers an edge of the pixel electrode PE and exposes a portion of an upper surface of the pixel electrode PE.

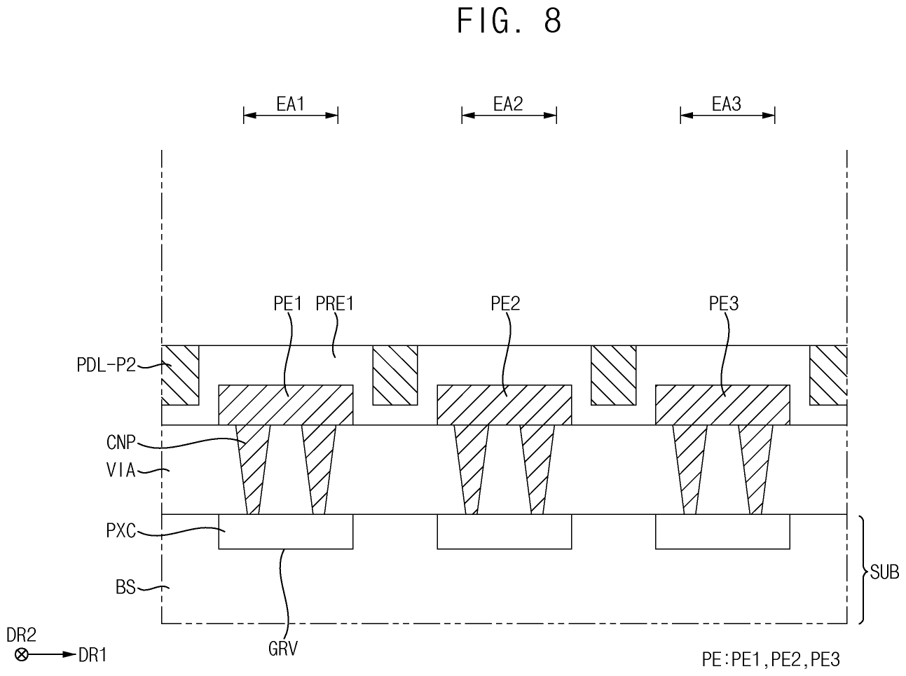

In some embodiments, the pixel defining layer PDL has a flat upper surface. As will be described later with reference to FIG. 8, because the upper surface of the pixel defining layer PDL may be formed through a polishing process, the pixel defining layer PDL may have the flat upper surface.

In some embodiments, the pixel defining layer PDL includes an inorganic material. Examples of the inorganic material that may be used as the pixel defining layer PDL may include silicon oxide (SiO₂), silicon nitride (SiNₓ), silicon oxynitride (SiON), or the like. These may be used alone or in combination with each other.

As illustrated in FIG. 3, the pixel defining layer PDL may include a first portion PDL-P1 and a second portion PDL-P2. The first portion PDL-P1 of the pixel defining layer PDL may define the pixel opening and cover at least a portion of the pixel electrode PE. The first portion PDL-P1 of the pixel defining layer PDL may form a step difference (e.g., a step structure) on the upper surface of the pixel electrode PE. For example, a portion of the first portion PDL-P1 may be within an opening of the pixel electrode PE and a portion of the first portion PDL-P1 may protrude above the upper surface of the pixel electrode PE.

The first portion PDL-P1 of the pixel defining layer PDL may surround the second portion PDL-P2 of the pixel defining layer PDL in a plan view. In other words, the side and bottom surfaces of the second portion PDL-P2 of the pixel defining layer PDL may be covered by the first portion PDL-P1 of the pixel defining layer PDL.

In some embodiments, the first portion PDL-P1 of the pixel defining layer PDL and the second portion PDL-P2 of the pixel defining layer PDL include different inorganic materials. For example, the first portion PDL-P1 of the pixel defining layer

PDL may include silicon nitride (SiNₓ), and the second portion PDL-P2 of the pixel defining layer PDL may include silicon oxide (SiO₂).

The light emitting layer EML may be disposed on the pixel electrode PE while exposing (e.g., not covering/overlapping) part of the pixel electrode PE. The light emitting layer EML may include at least one of an organic light emitting material and a quantum dot. The light emitting layer EML may further include at least one of a hole injection layer, a hole transport layer, an electron transport layer, and an electron injection layer as an auxiliary layer for assisting light emitting.

In some embodiments, the light emitting layer EML has a tandem structure. In some examples, the light emitting layer EML may have a single layer structure including one light emitting layer.

The light emitting layer EML may include a first light emitting layer EML1, a second light emitting layer EML2, and a third light emitting layer EML3. The first light emitting layer EML1 disposed on an upper surface of the first pixel electrode PE1 in the first light emitting area EA1 may emit a first light. The second light emitting layer EML2 disposed on an upper surface of the second pixel electrode PE2 in the second light emitting area EA2 may emit a second light. The third light emitting layer EML3 disposed on an upper surface of the third pixel electrode PE3 in the third light emitting area EA3 may emit a third light. In some embodiments, the first light is red light, the second light is green light, and the third light is blue light.

The separators SP may be disposed on the pixel defining layer PDL. For example, the separators SP may be disposed on the second portion PDL-P2 of the pixel defining layer PDL. However, the present disclosure is not limited thereto, and the separators SP may be disposed on the first portion PDL-P1 of the pixel defining layer

PDL. The separators SP may be spaced apart from each other in a plan view. For example, the separators SP may be disposed on the pixel defining layer PDL between the first light emitting area EA1 and the second light emitting area EA2 or between the second light emitting area EA2 and the third light emitting area EA3. However, the present disclosure is not limited thereto.

In some embodiments, the separators SP includes an inorganic material. Examples of the inorganic material that may be used as the separators SP may include silicon oxide (SiO₂), silicon nitride (SiNₓ), silicon oxynitride (SiON), or the like. These may be used alone or in combination with each other.

As illustrated in FIG. 3, in some embodiments, each of the separators SP includes a first inorganic layer SP-L1 and a second inorganic layer SP-L2 disposed on the first inorganic layer SP-L1. The first inorganic layer SP-L1 and the second inorganic layer SP-L2 may include different inorganic materials. For example, the first inorganic layer SP-L1 may include silicon nitride (SiNₓ), and the second inorganic layer SP-L2 may include silicon oxide (SiO₂).

In some embodiments, the second inorganic layer SP-L2 defines an undercut shape together with the first inorganic layer SP-L1. In other words, a side surface of the second inorganic layer SP-L2 may protrude further in a direction away from a center of the first inorganic layer SP-L1 (e.g., along the first direction DR1) than a side surface of the first inorganic layer SP-L1. That is, a width of the second inorganic layer SP-L2 may be greater than a width of the first inorganic layer SP-L1. Therefore, an edge of the second inorganic layer SP-L2 may extend past the side surface of the first inorganic layer SP-L1.

As each of the separators SP has the undercut shape, current leakage from the first light emitting layer EML1 to the second light emitting layer EML2 adjacent to the first light emitting layer EML1 may be reduced. Similarly, current leakage from the second light emitting layer EML2 to each of the first light emitting layer EML1 and the third light emitting layer EML3 that are adjacent to the second light emitting layer EML2 may be reduced. Accordingly, a color mixing phenomenon caused by unnecessary light emitting of adjacent light emitting layers may be suppressed.

In addition, each of the separators SP may function as a spacer. For example, each of the separators SP may prevent sagging of a fine metal mask (FMM).

The common electrode CE may be disposed on the pixel defining layer PDL, the light emitting layer EML, and the separators SP. The common electrode CE may extend along the first light emitting area EA1, the second light emitting area EA2, and the third light emitting area EA3. The common electrode CE may be integrally formed along the first light emitting area EA1, the second light emitting area EA2, and the third light emitting area EA3. However, the present disclosure is not limited thereto. For example, the common electrode CE may be separately formed in each of the first light emitting area EA1, the second light emitting area EA2, and the third light emitting area EA3.

The common electrode CE may be conformally disposed with respect to lower structures (e.g., the pixel defining layer PDL, the separators SP, etc.) to reflect (e.g., to conform to) the step difference (e.g., the step structure) of the lower structures. The common electrode CE may be disposed with a uniform thickness along the profiles of the pixel defining layer PDL, the light emitting layer EML, and the separators SP.

The common electrode CE may include a metal, an alloy, a metal nitride, a conductive metal oxide, a transparent conductive material, or the like. These may be used alone or in combination with each other.

Accordingly, the light emitting element LD including the pixel electrode PE, the light emitting layer EML, and the common electrode CE may be formed.

The encapsulation layer TFE may be disposed on the common electrode CE. The encapsulation layer TFE may prevent impurities, moisture, and the like from permeating the light emitting element LD from the outside, or may substantially reduce such permeation. The encapsulation layer TFE may include at least one inorganic layer and at least one organic layer. For example, the inorganic layer may include silicon oxide, silicon nitride, silicon oxynitride, or the like. These may be used alone or in combination with each other. For example, the organic layer may include a polymer cured material such as polyacrylate.

In the display device DD according to some embodiments of the present disclosure, the light emitting layer EML including a light emitting material emitting one color is independently disposed in each of the first to third light emitting areas EA1, EA2, and EA3. That is, the first light emitting layer EML1 disposed in the first light emitting area EA1 may emit a first light, and the second light emitting layer EML2 disposed in the second light emitting area EA2 may emit a second light. The third light emitting layer EML3 disposed in the third light emitting area EA3 may emit a third light. Accordingly, compared to a case where a light emitting layer EML is disposed to extend along the first to third light emitting areas EA1, EA2, and EA3 to emit one light (e.g., white light), the power consumption of the display device DD may be relatively reduced.

FIG. 4 is a cross-sectional view taken along the line II-II′ of FIG. 1, according to some embodiments of the present disclosure. For example, FIG. 4 is a cross-sectional view of the pad electrode PDE disposed in the pad area PA of FIG. 1. Hereinafter, descriptions overlapping those of the display device DD provided with reference to FIGS. 2 and 3 will be omitted or simplified.

Referring to FIG. 4, the display device DD according to some embodiments of the present disclosure includes the substrate SUB, the via-insulating layer VIA, the connection pattern CNP, the pad electrode PDE, the pixel defining layer PDL, a cover electrode PL, and the separators SP in the pad area PA.

The substrate SUB may include the base substrate (e.g., the base substrate BS of FIG. 2) and a plurality of lines. In some embodiments, the substrate SUB is a semiconductor circuit board.

The via-insulating layer VIA may be disposed on the substrate SUB. In some embodiments, the via-insulating layer VIA defines the via opening. The via opening may expose a portion of the plurality of lines.

The connection pattern CNP may be disposed on the substrate SUB. For example, the connection pattern CNP may be disposed in the via opening defined by the via-insulating layer VIA. The connection pattern CNP may electrically connect the plurality of lines and the pad electrode PDE.

The pad electrode PDE may be disposed on the via-insulating layer VIA and the connection pattern CNP. The pad electrode PDE may be connected to the plurality of lines through the connection pattern CNP. In some embodiments, the pad electrode PDE is a (semi-)transmissive electrode or a reflective electrode. For example, the pad electrode PDE may include a first electrode layer including indium tin oxide (ITO), a second electrode layer disposed on the first electrode layer and including silver (Ag), and a third electrode layer disposed on the second electrode layer and including indium tin oxide (ITO). According to some examples, the pad electrode PDE may include the same material as the pixel electrode (e.g., the pixel electrode PE of FIG. 2) and may be formed through the same process.

The pixel defining layer PDL may be disposed on the via-insulating layer VIA and the pad electrode PDE. The pixel defining layer PDL may include the first portion PDL-P1 and the second portion PDL-P2. The first portion PDL-P1 of the pixel defining layer PDL may define a pad opening and may cover at least a portion of the pad electrode PDE. The second portion PDL-P2 of the pixel defining layer PDL may contact the first portion PDL-P1 of the pixel defining layer PDL. For example, the side and bottom surfaces of the second portion PDL-P2 of the pixel defining layer PDL may be covered by the first portion PDL-P1 of the pixel defining layer PDL.

The cover electrode PL may be disposed on the pixel defining layer PDL and the pad electrode PDE, while exposing part of the pixel defining layer PDL. For example, the cover electrode PL may cover an upper surface (e.g., an entirety of the upper surface) of the pad electrode PDE in a plan view. In addition, the cover electrode PL may cover an edge of the pixel defining layer PDL and expose (e.g., not cover) a portion of an upper surface of the pixel defining layer PDL. The cover electrode PL may prevent impurities, moisture, and the like from permeating the pad electrode PDE from the outside, or substantially reduce such permeation.

The cover electrode PL may include a metal, an alloy, a metal nitride, a conductive metal oxide, a transparent conductive material, or the like. These may be used alone or in combination with each other. In some embodiments, the cover electrode PL includes titanium nitride (TiN).

The separators SP may be disposed on the pixel defining layer PDL and the cover electrode PL. For example, the separators SP may be disposed on portions of the upper surface of the pixel defining layer PDL that are exposed by (e.g., not covered by) the cover electrode PL. In addition, the separators SP may cover an edge of the cover electrode PL and may expose (e.g., not cover) a portion of an upper surface of the cover electrode PL.

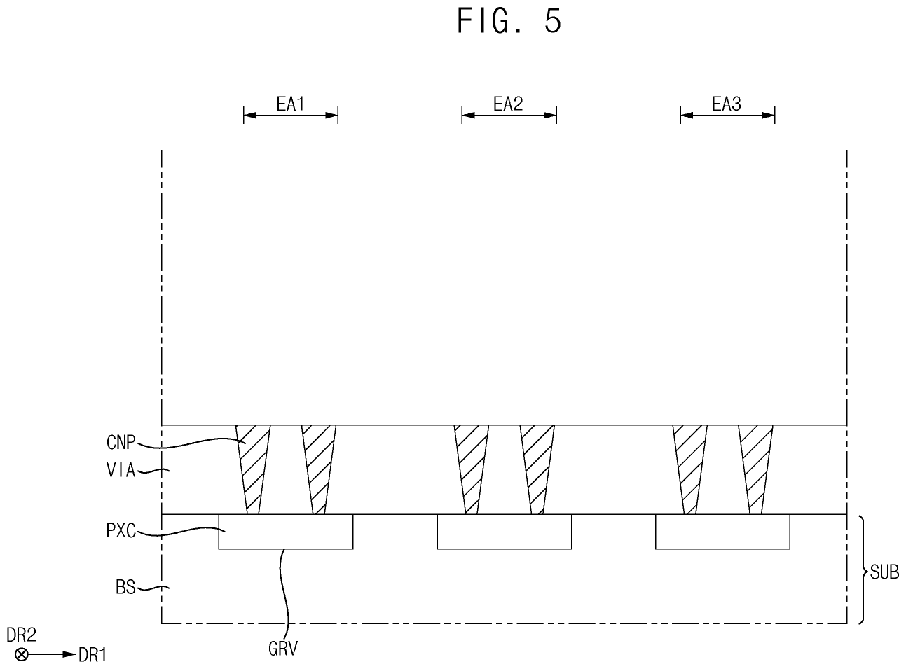

FIGS. 5, 6, 7, 8, 9, 10, and 11 are cross-sectional views illustrating a method for manufacturing a display device according to some embodiments of the present disclosure. The method for manufacturing the display device described with reference to FIGS. 5 to 11 maybe the method for manufacturing the display device DD described with reference to FIGS. 1, 2, 3, and 4. Hereinafter, descriptions overlapping those of the display device DD provided with reference to FIGS. 1, 2, 3, and 4 will be omitted or simplified.

Referring to FIG. 5, the via-insulating layer VIA may be formed on the substrate SUB. The via-insulating layer VIA may include an organic material or an inorganic material. In some embodiments, the via-insulating layer VIA defines the via opening. The via opening may expose a portion of the pixel circuit parts PXC.

The connection pattern CNP may be formed on the substrate SUB. For example, the connection pattern CNP may be disposed in the via opening defined by the via-insulating layer VIA. The connection pattern CNP may include a metal, an alloy, a metal nitride, a conductive metal oxide, a transparent conductive material, or the like. These may be used alone or in combination with each other. In some embodiments, the connection pattern CNP includes tungsten (W).

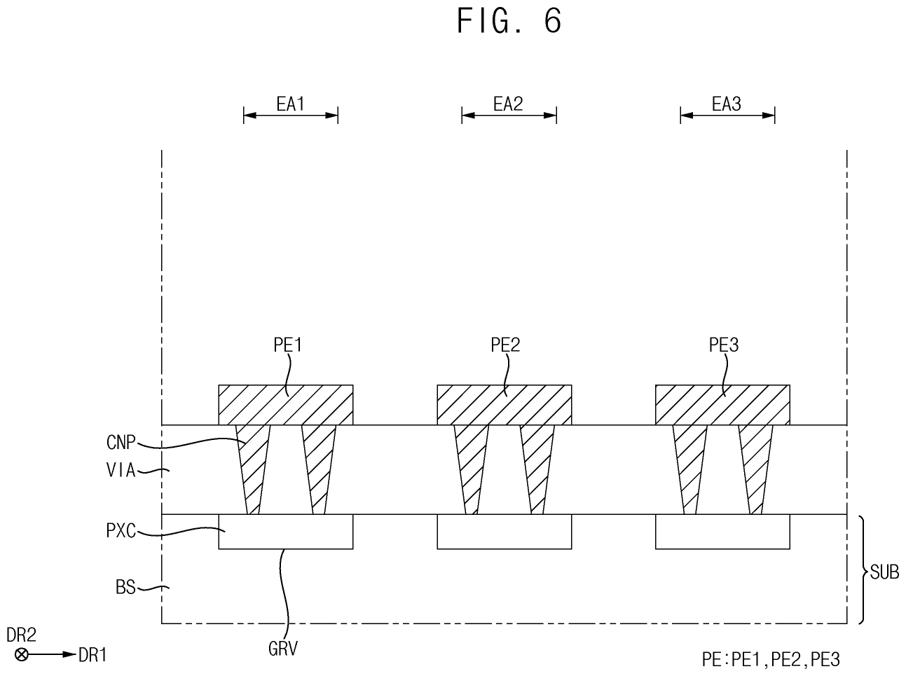

Referring further to FIG. 6, the pixel electrode PE may be formed on the via-insulating layer VIA and the connection pattern CNP. The pixel electrode PE may include the first pixel electrode PE1, the second pixel electrode PE2, and the third pixel electrode PE3.

The first pixel electrode PE1 may be formed on the via-insulating layer VIA and the connection pattern CNP in the first light emitting area EA1. The second pixel electrode PE2 may be formed on the via-insulating layer VIA and the connection pattern CNP in the second light emitting area EA2 . The third pixel electrode PE3 may be formed on the via-insulating layer VIA and the connection pattern CNP in the third light emitting area EA3.

The pixel electrode PE may include a metal, an alloy, a metal nitride, a conductive metal oxide, a transparent conductive material, or the like. These may be used alone or in combination with each other.

The pixel electrode PE may have a multilayer structure. For example, the pixel electrode PE may include the first electrode layer including indium tin oxide (ITO), the second electrode layer disposed on the first electrode layer and including silver (Ag), and the third electrode layer disposed on the second electrode layer and including indium tin oxide (ITO).

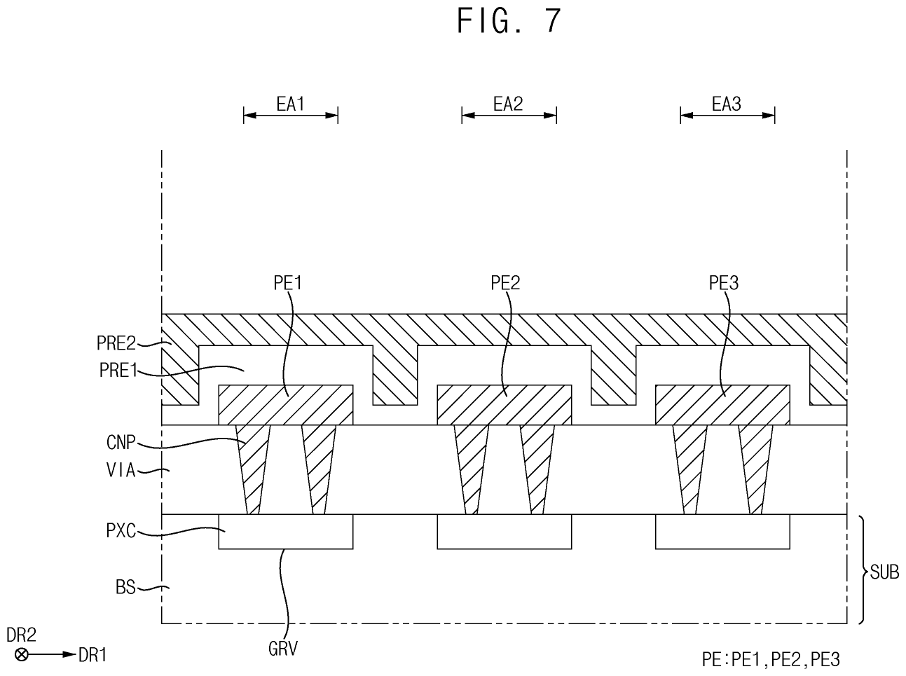

Referring further to FIG. 7, a first preliminary layer PRE1 may be formed on the via-insulating layer VIA and the pixel electrode PE.

The first preliminary layer PRE1 may cover the via-insulating layer VIA and the pixel electrode PE and may be formed to have a uniform thickness along the profiles of the via-insulating layer VIA and the pixel electrode PE. Accordingly, the first preliminary layer PRE1 may define a groove. In some embodiments, the first preliminary layer PRE1 includes an inorganic material. For example, the first preliminary layer PRE1 may include silicon nitride (SiNₓ).

A second preliminary layer PRE2 may be formed on the first preliminary layer PRE1. For example, the second preliminary layer PRE2 may cover the first preliminary layer PRE1 and may fill the groove defined by the first preliminary layer

PRE1. In some embodiments, the second preliminary layer PRE2 and the first preliminary layer PRE1 includes different inorganic materials. For example, the second preliminary layer PRE2 may include silicon oxide (SiO₂).

Referring further to FIG. 8, the second portion PDL-P2 of the pixel defining layer PDL that fills the groove and has a flat upper surface may be formed by removing a portion of the second preliminary layer PRE2.

In some embodiments, the portion of the second preliminary layer PRE2 is removed through a polishing process. For example, the polishing process may be a chemical mechanical polishing (CMP) process in which mechanical removal processing and chemical removal processing are mixed as one processing method.

The upper surface of the second portion PDL-P2 of the pixel defining layer PDL and an upper surface of the first preliminary layer PRE1 may be planarized through the polishing process.

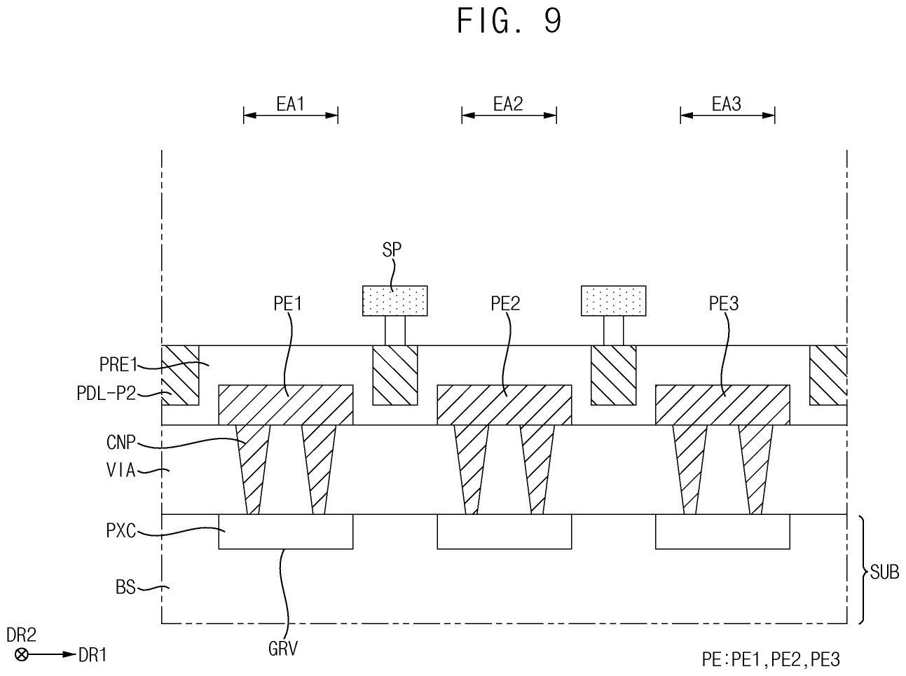

Referring further to FIG. 9, the separators SP may be formed on the second portion PDL-P2 of the pixel defining layer PDL.

The separators SP may be formed to be spaced apart from each other in a plan view. For example, the separators SP may be formed on the second portion PDL-P2 of the pixel defining layer PDL between the first light emitting area EA1 and the second light emitting area EA2 or between the second light emitting area EA2 and the third light emitting area EA3. However, the present disclosure is not limited thereto.

Each of the separators SP may include the first inorganic layer (e.g., the first inorganic layer SP-L1 of FIG. 3) and the second inorganic layer (e.g., the second inorganic layer SP-L2 of FIG. 3) disposed on the first inorganic layer. In some embodiments, the first inorganic layer and the second inorganic layer includes different inorganic materials. For example, the first inorganic layer may include silicon nitride

(SiNₓ), and the second inorganic layer may include silicon oxide (SiO₂).

In some embodiments, the second inorganic layer defines an undercut shape together with the first inorganic layer. The undercut shape may be formed by removing a portion of the first inorganic layer through an etching process. In other words, the side surface of the second inorganic layer may protrude more in a direction away from the center of the first inorganic layer (e.g., along the first direction DR1) than the side surface of the first inorganic layer. Therefore, an edge of the second inorganic layer may extend past the side surface of the first inorganic layer.

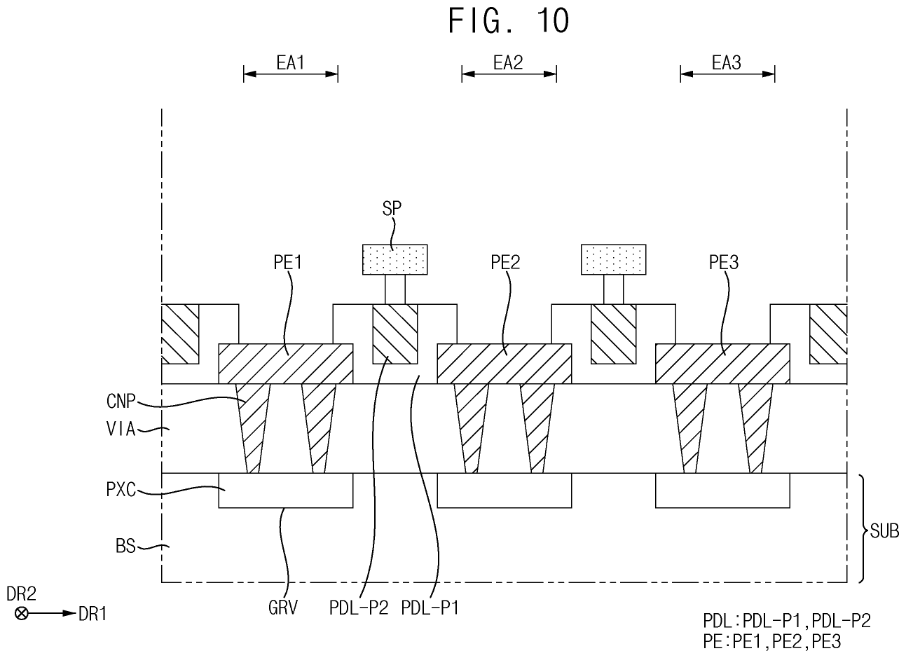

Referring further to FIG. 10, the first portion PDL-P1 of the pixel defining layer PDL may be formed by patterning the first preliminary layer PRE1.

For example, the first portion PDL-P1 of the pixel defining layer PDL may be formed by removing a portion of the first preliminary layer PRE1 through an etching process. The first portion PDL-P1 of the pixel defining layer PDL may define the pixel opening exposing at least a portion of the upper surface of the pixel electrode PE. In other words, the first portion PDL-P1 of the pixel defining layer PDL may cover at least a portion of the pixel electrode PE.

As the first preliminary layer PRE1 has a flat upper surface, the first portion PDL-P1 of the pixel defining layer PDL may have a flat upper surface. The first portion PDL-P1 of the pixel defining layer PDL may form a step difference (e.g., a step structure) on the upper surface of the pixel electrode PE.

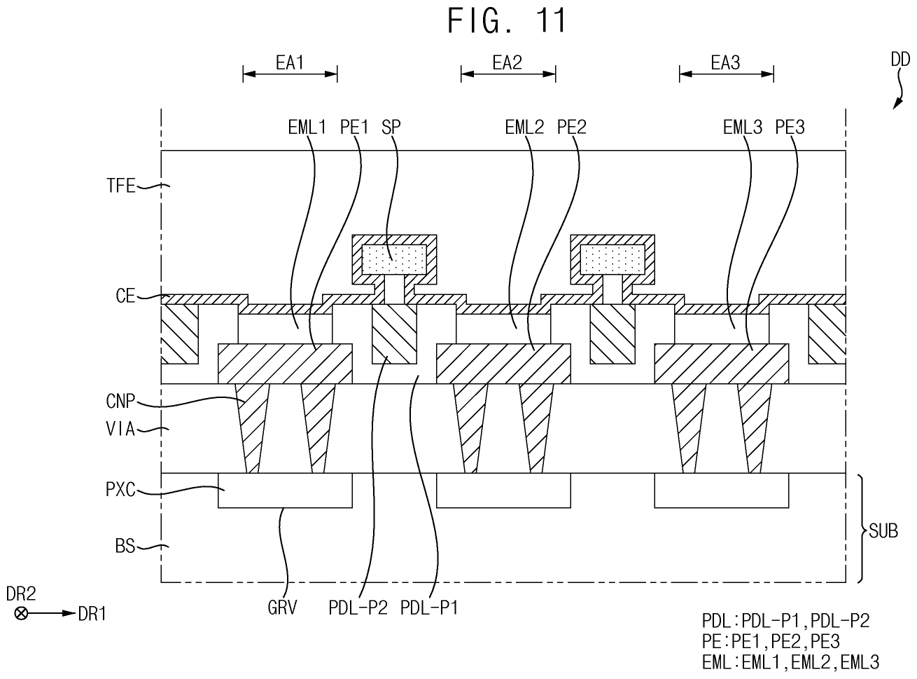

Referring further to FIG. 11, the light emitting layer EML may be formed on the pixel electrode PE, while exposing at least a part of the pixel electrode PE.

The light emitting layer EML may include the first light emitting layer EML1, the second light emitting layer EML2, and the third light emitting layer EML3. The first light emitting layer EML1 may be formed on the upper surface of the first pixel electrode PE1 in the first light emitting area EA1. The second light emitting layer EML2 may be formed on the upper surface of the second pixel electrode PE2 in the second light emitting area EA2. The third light emitting layer EML3 may be formed on the upper surface of the third pixel electrode PE3 in the third light emitting area EA3.

The common electrode CE may be formed on the light emitting layer EML, the pixel defining layer PDL, and the separators SP. For example, the common electrode CE may be formed to extend along the first light emitting area EA1, the second light emitting area EA2, and the third light emitting area EA3. In addition, the common electrode CE may be formed to have a uniform thickness along the profiles of the light emitting layer EML, the pixel defining layer PDL, and the separators SP. The common electrode CE may include a metal, an alloy, a metal nitride, a conductive metal oxide, a transparent conductive material, or the like. These may be used alone or in combination with each other.

The encapsulation layer TFE may be formed on the common electrode CE. The encapsulation layer TFE may include at least one inorganic layer and at least one organic layer.

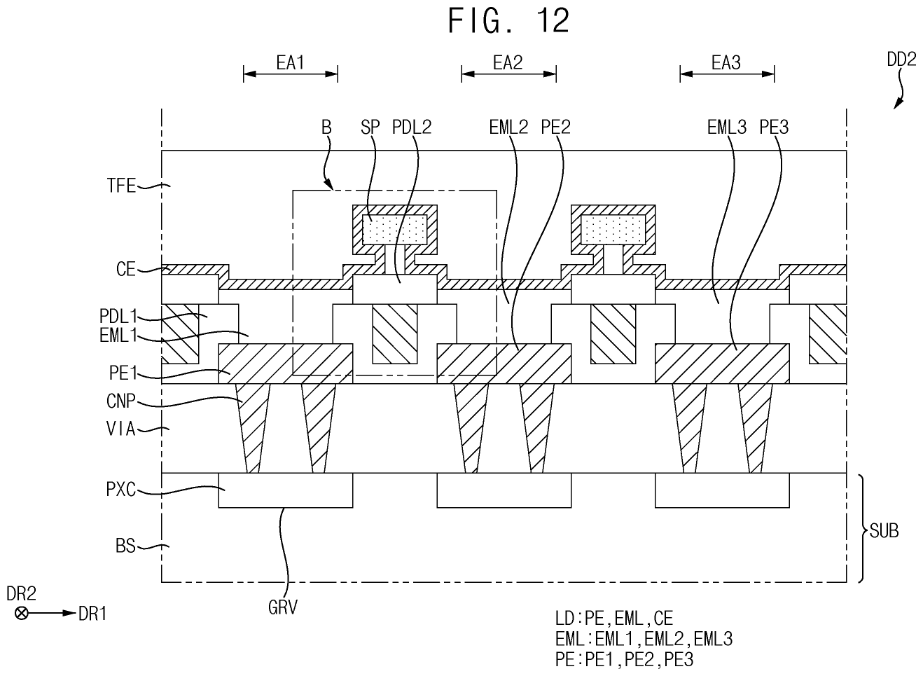

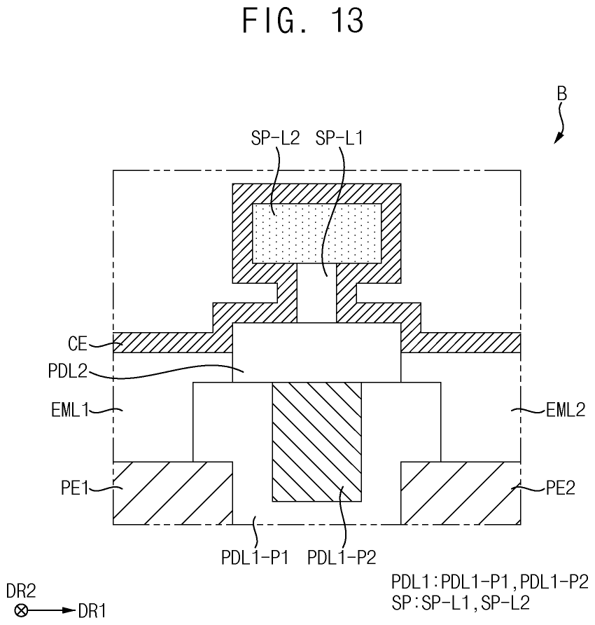

FIG. 12 is a cross-sectional view illustrating a display device according to some other embodiments of the present disclosure. FIG. 13 is an enlarged cross-sectional view of area ‘B’ of FIG. 12.

Referring to FIGS. 12 and 13, a display device DD2 may include the substrate SUB, the via-insulating layer VIA, the connection pattern CNP, the light emitting element LD, a first pixel defining layer PDL1, a second pixel defining layer PDL2, the separators SP, and the encapsulation layer TFE. The light emitting element LD may include the pixel electrode PE, the light emitting layer EML, and the common electrode CE.

The first pixel defining layer PDL1 illustrated in FIG. 12 maycorrespond to the pixel defining layer PDL illustrated in FIG. 2. That is, the display device DD2 may be substantially the same as the display device DD described with reference to FIGS. 2 and 3, except for the second pixel defining layer PDL2. Hereinafter, descriptions overlapping those of the display device DD provided with reference to FIGS. 2 and 3 will be omitted or simplified.

The first pixel defining layer PDL1 may be disposed on the via-insulating layer VIA and the pixel electrode PE. The first pixel defining layer PDL1 may have a flat upper surface. The first pixel defining layer PDL1 may include an inorganic material. Examples of the inorganic material that may be used as the first pixel defining layer PDL1 may include silicon oxide (SiO₂), silicon nitride (SiNₓ), silicon oxynitride

(SiON), or the like. These may be used alone or in combination with each other.

The first pixel defining layer PDL1 may include a first portion PDL1-P1 and a second portion PDL1-P2. The first portion PDL1-P1 of the first pixel defining layer PDL1 may cover at least a portion of the pixel electrode PE and define an opening exposing a portion of the upper surface of the pixel electrode PE. The side and bottom surfaces of the second portion PDL1-P2 of the first pixel defining layer PDL1 may be covered by the first portion PDL1-P1 of the first pixel defining layer PDL1.

In some embodiments, the first portion PDL1-P1 of the first pixel defining layer PDL1 and the second portion PDL1-P2 of the first pixel defining layer PDL1 includes different inorganic materials. For example, the first portion PDL1-P1 of the first pixel defining layer PDL1 may include silicon nitride (SiNₓ), and the second portion PDL1-P2 of the first pixel defining layer PDL1 may include silicon oxide (SiO₂). The first portion PDL1-P1 of the first pixel defining layer PDL1 may form a step difference (e.g., a step structure) on the upper surface of the pixel electrode PE.

The second pixel defining layer PDL2 may be disposed on the first pixel defining layer PDL1. The second pixel defining layer PDL2 may have a flat upper surface.

In some embodiments, a side surface of the first pixel defining layer PDL1 protrudes more in a direction away from a center of the second pixel defining layer PDL2 than a side surface of the second pixel defining layer PDL2. That is, a width of the first pixel defining layer PDL1 may be greater than a width of the second pixel defining layer PDL2.

Accordingly, the second pixel defining layer PDL2 may form a step difference (e.g., a step structure) on an upper surface of the first pixel defining layer PDL1, and may form a double step difference (e.g., a double step structure) with the first portion PDL1-P1 of the first pixel defining layer PDL1.

In some embodiments, the second pixel defining layer PDL2 includes an inorganic material. Examples of the inorganic material that may be used as the second pixel defining layer PDL2 may include silicon oxide (SiO₂), silicon nitride (SiNₓ), silicon oxynitride (SiON), or the like. These may be used alone or in combination with each other.

The light emitting layer EML may be disposed on the pixel electrode PE, while exposing at least a part of the pixel electrode PE. For example, the light emitting layer EML may cover the side surface of the first pixel defining layer PDL1 that protrudes more in a direction away from the center of the second pixel defining layer PDL2 than the side surface of the second pixel defining layer PDL2. In addition, the light emitting layer EML may contact the side surface of the second pixel defining layer PDL2.

The separators SP may be disposed on the second pixel defining layer PDL2. The separators SP may be spaced apart from each other in a plan view. For example, the separators SP may be disposed on the second pixel defining layer PDL2 between the first light emitting area EA1 and the second light emitting area EA2 or between the second light emitting area EA2 and the third light emitting area EA3. However, the present disclosure is not limited thereto.

The common electrode CE may be disposed on the second pixel defining layer PDL2, the light emitting layer EML, and the separators SP. The common electrode CE may be conformally disposed with respect to a lower structure (e.g., the second pixel defining layer PDL2, the separators SP, etc.) to reflect the step difference of the lower structure. That is, the common electrode CE may be disposed with a uniform thickness along the profiles (e.g., outer surfaces) of the second pixel defining layer PDL2, the light emitting layer EML, and the separators SP.

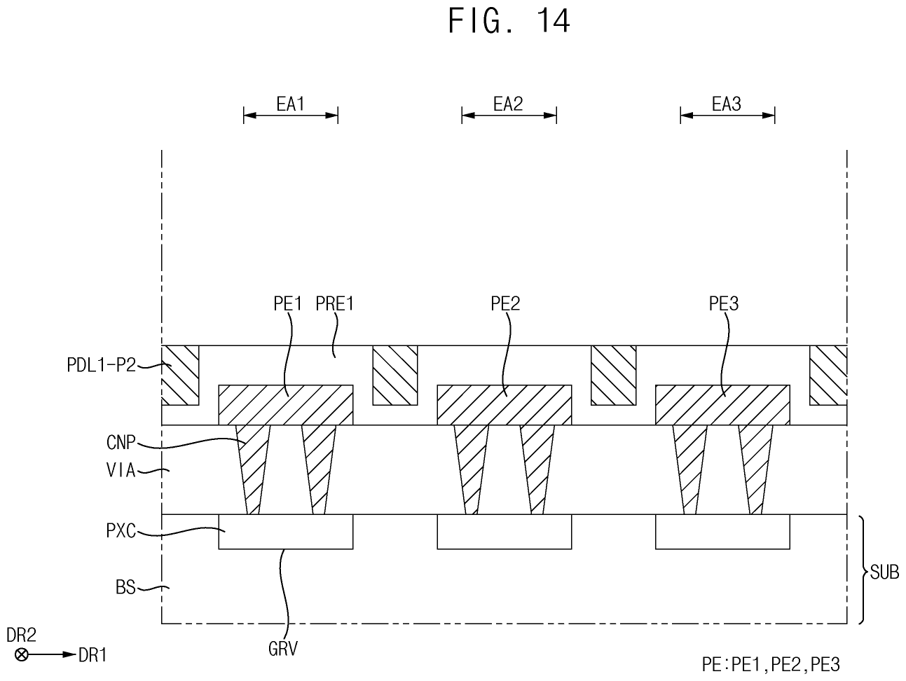

FIGS. 14, 15, 16, and 17 are cross-sectional views illustrating a method for manufacturing a display device according to some other embodiments of the present disclosure. The method for manufacturing the display device with reference to FIGS. 14 to 17 maybe the method for manufacturing the display device DD2 described with reference to FIGS. 12 and 13. Hereinafter, descriptions overlapping those of the method for manufacturing the display device provided with reference to FIGS. 5, 6, 7, 8, 9, 10, and 11 will be omitted or simplified.

Referring to FIG. 14, the via-insulating layer VIA and the connection pattern CNP may be formed on the substrate SUB, and the pixel electrode PE may be formed on the via-insulating layer VIA and the connection pattern CNP. The first preliminary layer PRE1 may be formed on the via-insulating layer VIA and the pixel electrode PE, and the second preliminary layer PRE2 may be formed on the first preliminary layer PRE1 (e.g., as shown in FIG. 7). The second preliminary layer PRE2 may cover the first preliminary layer PRE1 and fill the groove defined by the first preliminary layer PRE1.

After forming the second preliminary layer PRE2, a portion of the second preliminary layer PRE2 may be removed to form the second portion PDL1-P2 of the first pixel defining layer PDL1 that fills the groove and has a flat upper surface.

In some embodiments, the portion of the second preliminary layer PRE2 is removed through a polishing process. For example, the polishing process may be a CMP process.

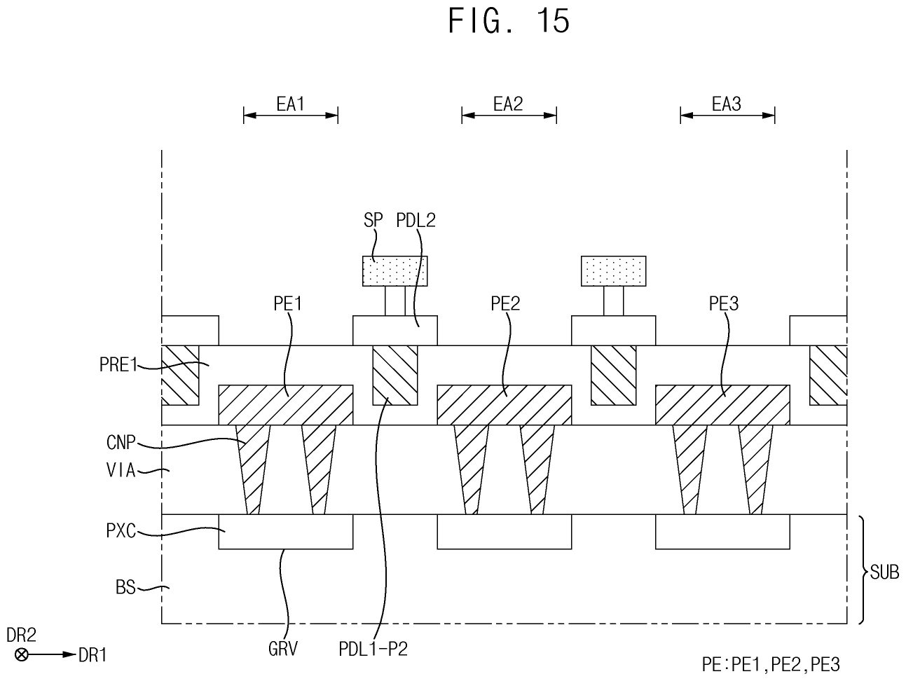

Referring further to FIG. 15, the second pixel defining layer PDL2 may be formed on the first preliminary layer PRE1 and the second portion PDL1-P2 of the first pixel defining layer PDL1.

That is, the second pixel defining layer PDL2 may overlap the second portion PDL1-P2 of the first pixel defining layer PDL1 in a plan view. In some embodiments, the second pixel defining layer PDL2 includes an inorganic material.

The separators SP may be formed on the second pixel defining layer PDL2. The separators SP may be formed to be spaced apart from each other in a plan view. Each of the separators SP may include the first inorganic layer (e.g., the first inorganic layer SP-L1 of FIG. 13) and the second inorganic layer (e.g., the second inorganic layer SP-L2 of FIG. 13) disposed on the first inorganic layer. In some embodiments, the second inorganic layer defines an undercut shape together with the first inorganic layer.

In some embodiments, the first inorganic layer and the second inorganic layer include different inorganic materials. For example, the first inorganic layer may include silicon nitride (SiNₓ), and the second inorganic layer may include silicon oxide (SiO₂).

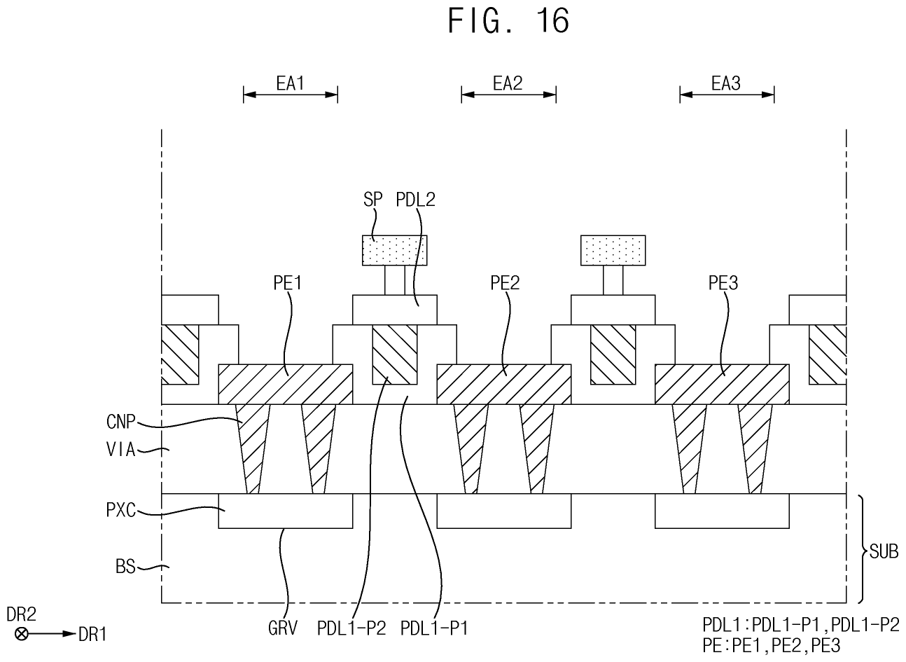

Referring further to FIG. 16, the first portion PDL1-P1 of the first pixel defining layer PDL1 may be formed by patterning the first preliminary layer PRE1.

For example, the first portion PDL1-P1 of the first pixel defining layer PDL1 may be formed by removing a portion of the first preliminary layer PRE1 through an etching process. As the first preliminary layer PRE1 has the flat upper surface, the first portion PDL1-P1 of the first pixel defining layer PDL1 may have a flat upper surface. The first portion PDL1-P1 of the first pixel defining layer PDL1 may form a step difference (e.g., a step structure) on the upper surface of the pixel electrode PE.

In some embodiments, the side surface of the first part PDL1-P1 of the first pixel defining layer PDL1 is formed to protrude more in a direction away from the center of the second pixel defining layer PDL2 than the side surface of the second pixel defining layer PDL2. That is, the width of the first pixel defining layer PDL1 may be greater than the width of the second pixel defining layer PDL2. Herein, the widths may be defined along the first direction DR1.

Accordingly, the second pixel defining layer PDL2 may form a step difference (e.g., a step structure) on the upper surface of the first pixel defining layer PDL1 and may form a double step difference (e.g., a double step structure) with the first portion PDL1-P1 of the first pixel defining layer PDL1.

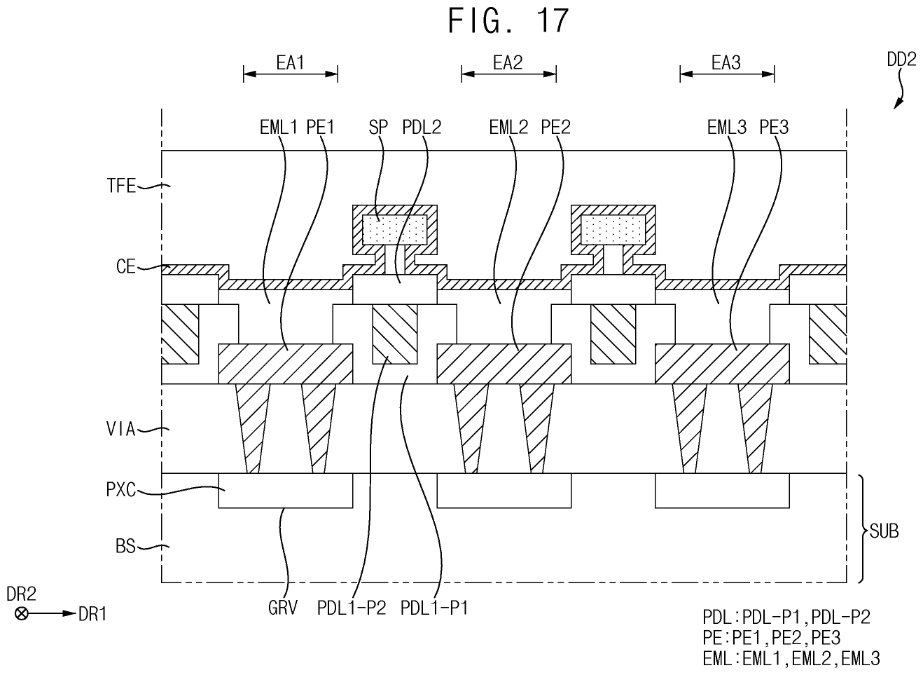

Referring further to FIG. 17, the light emitting layer EML may be formed on the pixel electrode PE.

For example, the light emitting layer EML may cover the side surface of the first pixel defining layer PDL1 that protrudes more in a direction away from the center of the second pixel defining layer PDL2 than the side surface of the second pixel defining layer PDL2.

The common electrode CE may be formed on the light emitting layer EML, the second pixel defining layer PDL2, and the separators SP. The common electrode CE may be formed to have a uniform thickness along the profiles of the light emitting layer EML, the second pixel defining layer PDL2, and the separators SP.

The encapsulation layer TFE may be formed on the common electrode CE. The encapsulation layer TFE may include at least one inorganic layer and at least one organic layer.

The present disclosure may be applied to various display devices. For example, embodiments of the present disclosure may be applicable to various display devices such as display devices for vehicles, ships and aircraft, portable communication devices, display devices for exhibition or information transmission, medical display devices, and the like.

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art.

As used herein, the terms “use,” “using,” and “used” may be considered synonymous with the terms “utilize,” “utilizing,” and “utilized,” respectively.

The foregoing is illustrative of the embodiments of the present disclosure, and is not to be construed as limiting thereof. Although some embodiments have been described with reference to the figures, those skilled in the art will readily appreciate that many variations and modifications may be made therein without departing from the spirit and scope of the present disclosure as defined by the appended claims, and equivalents thereof.

What is claimed is:

1. A display device comprising:
a substrate;
a via-insulating layer on the substrate;
a first pixel electrode on the via-insulating layer;
a first pixel defining layer having a flat upper surface, on the via-insulating layer, and defining an opening exposing at least a portion of an upper surface of the first pixel electrode; and
separators on the first pixel defining layer and spaced apart from each other in a plan view.

2. The display device of claim 1, wherein the first pixel defining layer comprises:
a first portion defining the opening; and
a second portion having surfaces covered by the first portion.

3. The display device of claim 2, wherein the first pixel defining layer comprises an inorganic material, and
wherein the first portion comprises an inorganic material different from that of the second portion.

4. The display device of claim 3, wherein the first portion comprises silicon nitride, and the second portion comprises silicon oxide.

5. The display device of claim 1, wherein each of the separators comprises a first inorganic layer and a second inorganic layer on the first inorganic layer, and wherein the first inorganic layer comprises an inorganic material different from the second inorganic layer.

6. The display device of claim 5, wherein a side surface of the second inorganic layer protrudes more in a direction away from a center of the first inorganic layer than a side surface of the first inorganic layer.

7. The display device of claim 1, further comprising:
a second pixel defining layer between the first pixel defining layer and the separators,
wherein the second pixel defining layer overlaps the first pixel defining layer in the plan view.

8. The display device of claim 7, wherein a side surface of the first pixel defining layer protrudes more in a direction away from a center of the second pixel defining layer than a side surface of the second pixel defining layer.

9. The display device of claim 1, wherein the substrate comprises:
a base substrate defining a plurality of grooves and comprising a silicon wafer; and
a plurality of pixel circuit portions respectively accommodated in the plurality of grooves.

10. The display device of claim 9, further comprising:
a second pixel electrode and a third pixel electrode on the via-insulating layer; and
first, second, and third light emitting layers respectively on an upper surface of the first, second, and third pixel electrodes,
wherein the first light emitting layer, the second light emitting layer, and the third light emitting layer emit lights have different wavelengths.

11. A method for manufacturing a display device, the method comprising:
forming a via-insulating layer on a substrate;
forming a first pixel electrode on the via-insulating layer;
forming a first preliminary layer defining a groove on the via-insulating layer and the first pixel electrode;
forming a second preliminary layer that fills the groove on the first preliminary layer;
forming a second portion of a first pixel defining layer that fills the groove and has a flat upper surface by removing a portion of the second preliminary layer;
forming separators spaced apart from each other in a plan view on the second portion of the first pixel defining layer; and
forming a first portion of the first pixel defining layer that defines an opening exposing at least a portion of an upper surface of the first pixel electrode and has a flat upper surface by patterning the first preliminary layer.

12. The method of claim 11, wherein the first preliminary layer is formed along profiles of the via-insulating layer and the first pixel electrode.

13. The method of claim 11, wherein the first pixel defining layer comprises an inorganic material, and
wherein the first portion comprises an inorganic material different from the second portion.

14. The method of claim 11, wherein the forming of the second portion of the first pixel defining layer is performed through a polishing process.

15. The method of claim 11, wherein each of the separators comprises a first inorganic layer and a second inorganic layer on the first inorganic layer, and
wherein the first inorganic layer comprises an inorganic material different from that of the second inorganic layer.

16. The method of claim 15, wherein a side surface of the second inorganic layer protrudes more in a direction away from a center of the first inorganic layer than a side surface of the first inorganic layer.

17. The method of claim 11, further comprising:
forming a second pixel defining layer on the first preliminary layer and the second portion of the first pixel defining layer after the forming the second portion of the first pixel defining layer,
wherein the second pixel defining layer is between the second portion of the first pixel defining layer and the separators.

18. The method of claim 17, wherein a side surface of the first portion of the first pixel defining layer protrudes more in a direction away from a center of the second pixel defining layer than a side surface of the second pixel defining layer.

19. The method of claim 11, wherein the substrate comprises a silicon wafer.

20. The method of claim 19, wherein the forming a first pixel electrode comprises:
forming a second pixel electrode and a third pixel electrode on the via-insulating layer,
wherein the method further comprises:
forming first, second, and third light emitting layers respectively on an upper surface of the first, second, and third pixel electrodes, and
wherein the first light emitting layer, the second light emitting layer, and the third light emitting layer are configured to emit lights having different wavelengths.
